(19) United States
(12) Patent Application Publication
(10) Pub. No.: US 2026/0298449 A1
(43) Pub. Date: Oct. 1, 2026

(54) Fastening system for an electronic circuit board

(71) Applicant: BEGA Gantenbrink-Leuchten KG, Menden (DE)

(72) Inventor: Michael Golew, Iserlohn (DE)

(73) Assignee: BEGA Gantenbrink-Leuchten KG, Menden (DE)

(21) Appl. No.: 19/632,508

(22) Filed: Mar. 30, 2026

(30) Foreign Application Priority Data
Mar. 31, 2025 (LU) LU600959

(51) Int. Cl. F21V 19/00; F21V 29/70; F21Y 115/10; H05K 1/02; H05K 1/03; H05K 1/181

(52) U.S. Cl. CPC F21V 19/004; F21V 29/70; H05K 1/0201; H05K 1/0278; H05K 1/028; H05K 1/0393; H05K 1/181; F21Y 2115/10; H05K 2201/066; H05K 2201/10106

(57) ABSTRACT

A fastening system serves for fastening an electronic circuit board (1) on a supporting part (2). The circuit board (1) has at least one elastically deformable fastening region (3) that, when inserted into a receiving structure of a retaining element (6) provided on the supporting part (2), can be brought into engagement by elastic deformation, so that a mechanical retaining connection can be produced.

### CROSS-REFERENCE TO RELATED APPLICATION

This application claims the benefit of Luxembourg Patent Application LU600959, filed on Mar. 31, 2025, the entire contents of which is incorporated by reference.

### TECHNICAL FIELD

The disclosure relates to a fastening system for an electronic circuit board on a supporting part and to a luminaire with such a circuit board.

### BACKGROUND

Electronic circuit boards, for example printed circuit boards with LED components, are typically fastened to a housing or carrier by screws, clamps, or additional retaining elements. These known fastening methods require additional components, tools, and assembly steps, which increases manufacturing and maintenance effort. In addition, particularly in the case of sensitive components such as LEDs, there is a risk of mechanical damage during installation or removal. The replacement or disassembly of the circuit board is often complex, especially in the case of limited installation space.

Solutions are also known in which circuit boards are fixed in a housing via latching or snap-in connections. However, these systems usually use separate clips, clamps, or elastic receptacles that are permanently connected to the housing. The circuit board itself remains a passive element in this case. Active participation of the circuit board in the fastening function is generally not provided.

EP 3 339 724 B1 discloses a luminaire with a support rail and a fastening element in which LED circuit boards are inserted into a support rail by latching means. The fastening is tool-free and uses separate retaining clips that snap into the support rail. The circuit board itself, however, is passive.

EP 2 873 913 B1 describes an LED luminaire in which a cover profile with snap hooks is pressed from above onto an LED circuit board. Fixation is likewise tool-free, but by separate fastening means that clamp the circuit board.

U.S. Pat. No. 10,251,279 B1 shows a fastening system in which a printed circuit board edge is inserted into a resilient latching slot with corresponding latching structures. The fastening means, however, are located exclusively in the carrier, while the circuit board merely has recesses. The circuit board itself is not elastically deformable, but rather is held by external springs.

A fundamentally different concept is shown by U.S. Pat. No. 6,934,162 B2, in which keyhole-shaped mounting holes of the circuit board cooperate with housing bolts. The circuit board is fixed by sliding in and subsequent locking.

In these known solutions, fastening of the circuit board always takes place by external mechanical elements, whether by housing structures or additionally mounted components. Accordingly, these solutions are either material-intensive or not very maintenance-friendly with respect to disassembly and replacement.

### SUMMARY

An object of the disclosure is to provide a fastening system that dispenses with additional releasable fastening means and allows tool-free assembly and disassembly. The object is achieved by the fastening system as disclosed and claimed.

A fastening system for an electronic circuit board on a supporting part is provided, the circuit board having at least one elastically deformable fastening region. This fastening region is configured such that, when the circuit board is inserted into a receiving structure of a retaining element provided on the supporting part, it can be brought into engagement by elastic deformation. In this way, a mechanical retaining connection between the circuit board and the supporting part can be produced without additional releasable fastening elements being required.

A substantial advantage of the fastening system consists in that the circuit board can be assembled without the use of tools and, if necessary, can also be disassembled again. The number of individual parts is reduced, since separate fastening means such as screws, clamps, or external clips can be dispensed with. By the direct participation of the circuit board in the retaining function, not only is additional installation space for external fastening elements eliminated, but material costs and assembly times are also reduced. At the same time, the risk of mechanical damage during assembly is reduced, in particular in the case of sensitive assemblies such as LED printed circuit boards.

In an advantageous embodiment, the mechanical retaining connection is formed as a positive-locking engagement between the elastically deformable fastening region of the circuit board and the retaining element of the supporting part. It is provided here that the fastening region of the circuit board elastically deforms during assembly in order, for example, to snap or latch into a corresponding undercut structure or recess of the retaining element. After engagement has taken place, the original shape of the fastening region advantageously at least partially restores itself, so that a defined geometric interlock between the two components is produced. This positive-locking embodiment offers the advantage that the retaining function is ensured primarily by the geometry of the elements that are in engagement with one another. This makes it possible to realize a secure, repeatable, and position-stable fastening. At the same time, the positive-locking connection enables exact positioning, for example with respect to light-technology-relevant components such as lenses or covers.

In a particularly advantageous embodiment, the elastically deformable fastening region of the circuit board is formed by a structural weakening or partial decoupling within the circuit board material, for example in the form of milled recesses, cuts, or openings. These regions are configured such that they allow elastic deformation in the installed state, in particular when being introduced into the receiving structure of the retaining element. The fastening region can have different geometries. Thus, the openings can be formed as round, oval, slot-shaped, or polygonal. Curved or segment-shaped cuts, U-shaped milled recesses, or circular-arc-like contours are also conceivable. Particularly suitable are geometries that locally generate high compliance without impairing the structural integrity of the circuit board overall. The arrangement of the cuts can be selected such that flexible tongues, webs, or tabs are formed in the edge region of the circuit board, which are elastically deflected during assembly and automatically return to their starting position after engagement. The preferred structural measures can be implemented easily within the scope of printed circuit board production, for example by milling or punching.

It is preferred that at least one elastically deformable fastening region is arranged in the edge region of the circuit board. The edge region is in particular the outer region of the printed circuit board that lies outside the electrically or thermally functional surfaces and can thus be used structurally for mechanical purposes without impairing active components. The arrangement in the edge region has several technical advantages: firstly, sufficient area is available there to accommodate fastening regions such as, for example, cuts, tabs, or flexible webs. Secondly, a circuit board with such edge structures can be introduced particularly easily into a retaining element, since no complex geometry within the usable area of the printed circuit board has to be taken into account. By positioning in the edge region, the elastically deformable fastening regions can be designed in a targeted manner such that, when the circuit board is inserted, they are first elastically deflected and then, by restoring, latch into the receiving structure of a retaining element.

In an alternative embodiment, at least one elastically deformable fastening region is arranged near a geometric center of the circuit board. The geometric center refers here to the center of area of the printed circuit board or a central region that is approximately equally far removed from the outer edges. The arrangement of such a fastening region in a central position can be advantageous in particular when additional stabilization of the circuit board in its center is desired or when no lateral access is possible due to the installation situation. By central fastening, tilting or twisting of the circuit board during or after assembly can be prevented, which is advantageous in particular in the case of large-area or mechanically sensitive circuit boards. The fastening in the central region can here be realized as described above by a targeted weakening of the material—for example by a central opening, a keyhole-shaped cutout, or a flexible tongue—that engages with a corresponding structure of a retaining element.

It is advantageous if the fastening system has a plurality of elastically deformable fastening regions and correspondingly matching retaining elements. Depending on the embodiment of the circuit board, the fastening regions can be arranged distributed over the circuit board. In a further preferred embodiment, the fastening system has two or four elastically deformable fastening regions that are each arranged opposite one another on opposite sides of the circuit board. These fastening regions are designed and positioned such that, when the circuit board is inserted, they can be brought into engagement with a respectively associated retaining element of the supporting part. The retaining elements are correspondingly provided pairwise opposite one another on the supporting part and form a symmetrical latching system with the associated fastening regions of the circuit board. This arrangement enables stable, all-round fixing in all spatial directions. Due to the opposite positioning of the fastening regions, uniform force conditions arise when inserting the circuit board, which favors low-stress assembly and minimizes mechanical loads on conductor tracks or components mounted on the circuit board. The number and position of the opposite fastening regions can be selected depending on the size, stiffness, and application of the circuit board. An arrangement with two opposite fastening points is suitable in particular for compact, rectangular printed circuit boards, whereas in the case of larger or mechanically stressed modules a four-point fastening ensures additional stability.

In an expedient development, the circuit board consists of a flexurally elastic material that enables the elastic deformability of the fastening regions required for the fastening function. Suitable materials include in particular glass-fiber-reinforced plastics such as FR4, which are widely used in electronics and have a good combination of mechanical strength and elastic compliance in the edge region. Alternatively, the circuit board can also consist of a flexible composite material that has been developed specifically for mechanically dynamic applications and offers increased restoring capability upon repeated deformation. For applications with increased heat generation, for example in the field of LED luminaires, a so-called metal-core substrate (e.g., aluminum-based) is also suitable, in which the printed circuit board is constructed on a thermally conductive carrier. These materials too can—given suitable design of the fastening regions—have sufficient elasticity for latching or clipping into a retaining structure.

In an advantageous embodiment, the supporting part has at least one retaining element that is formed as an undercut, latching lug, or snap projection. The retaining element is part of the receiving structure of the supporting part and serves to engage with the elastically deformable fastening region of the circuit board. The retaining element is designed such that, after the circuit board has been introduced, it forms a mechanical resistance that can only be overcome by elastic deformation of the fastening region. A retaining element formed as an undercut has in particular an under-gripping geometry that prevents rearward withdrawal of the circuit board without deformation. A latching lug can snap into a corresponding opening or recess of the circuit board and thus assume a position secured against displacement. Alternatively, a snap projection can be formed such that, when the circuit board is introduced, it is overridden by the elastic deflection of the fastening region and, after assembly, produces a restoring positive-locking engagement. By advantageously designed retaining elements, a defined, repeatable, and mechanically stable connection between circuit board and supporting part is achieved without releasable connecting means such as screws or clamping devices being required. The geometry of the retaining elements can here be adapted to the shape and elasticity of the fastening regions and enables an application-specific design with respect to retaining force, assembly travel, and restoring behavior.

In a preferred application, the circuit board comprises an LED module that serves, for example, as a carrier for light-emitting diodes (LEDs). This can be a conventional printed circuit board with surface-mounted devices (SMD) or a so-called chip-on-board module (COB), in which the LED chips are applied directly to the printed circuit board substrate and are contacted there. Particularly in the case of LED modules, reliable, stress-free, and at the same time compact fastening is of particular importance, since these assemblies are often thermally loaded and at the same time require exact positioning within an optical system—for example with respect to reflectors, lenses, or light guides. The fastening system enables precise and repeatable mounting of such LED modules without additional installation space for screws or retaining clips and thus reduces the design complexity of luminaires or LED carriers considerably. In addition, LED modules benefit from tool-free mountability, since they often have to be processed in series production or in replacement service. The retaining structure integrated into the circuit board or connected to it allows quick, damage-free installation and at the same time meets the high requirements for thermal coupling, vibration safety, and electrical insulation as are customary in the LED field.

It is preferred that the retaining connection is configured such that, in addition to its mechanical function, it enables a defined thermal connection and/or electrical isolation between the circuit board and the supporting part. This means that the fastening not only serves to fix the circuit board, but also contributes to heat dissipation and/or to electrical decoupling. The thermal connection is advantageous in particular in the case of LED modules, since the resulting waste heat must be efficiently dissipated to the housing or a heat sink in order to ensure the service life and luminous efficacy of the light-emitting diodes. By the fastening system, planar contact of the circuit board with the supporting part and thus close thermal contact can be achievable. Here, the supporting part can function as a heat conductor and dissipate the heat directly or via an intermediate layer (e.g., thermal pad). At the same time, the retaining connection can be designed such that a defined distance is maintained between electrical conductor structures on the circuit board and the supporting part. By using insulating materials in the region of the retaining elements or by geometrically limited contact surfaces, electrical decoupling can thus be realized that prevents the undershooting of creepage and clearance distances in accordance with relevant safety standards.

The supporting part can have different configurations depending on the specific application. In a preferred embodiment, the supporting part is a housing or a housing part of a luminaire. Alternatively, the supporting part can be a reflector element or an optics carrier, in particular when the circuit board is populated with light-emitting diodes and is intended to be positioned in the immediate vicinity of an optical system. In further embodiments, the supporting part can be an extruded carrier profile, as is used for example in linear luminaires or modular light strips. Likewise conceivable is a mounting plate or carrier plate, for example of thermally conductive plastic or metal, which serves both as a mechanical receiving means for the circuit board and for thermal connection. A heat sink, which can be part of the luminaire structure, can also function as a supporting part, provided it has the structures necessary for receiving the retaining elements.

In addition, the supporting part can be a housing base or retaining frame within an electronic module, for example in control units, sensor assemblies, or connection units. In certain embodiments, a component for strain relief or a mechanical cover element with latching geometry can also act as the supporting part, provided it contributes to the positive-locking and/or force-locking fixation of the circuit board. The construction of the supporting part is thus variable and can assume additional mechanical, thermal, or also electrical functions depending on system requirements.

It can be advantageous if the supporting part has positioning elements that form a stop for the retained circuit board. The positioning elements can be present in the form of edges, elevations, guide pins, ribs, shoulder surfaces, contact surfaces, stop lugs, or the like and prevent slipping of a retained circuit board on the supporting part. In this way, the positional securing or fixation of the circuit board can be improved.

The disclosure further relates to a luminaire comprising a fastening system, a housing, an electronic circuit board with at least one light-emitting diode (LED), and at least one retaining element provided on the housing for receiving and fixing the circuit board. For this purpose, the circuit board has at least one elastically deformable fastening region that, when inserted into a receiving structure of the retaining element, can be brought into engagement by elastic deformation. As a result, a mechanical retaining connection between the circuit board and the housing can be produced without additional releasable fastening elements being required. In particular, the disclosure relates to a luminaire with a fastening system explained above.

The luminaire can in particular comprise one or more lighting-technology and mechanical components, such as a lens, a transparent cover, a reflector element, a heat sink, a seal, or a connection and/or strain-relief unit. The electronic circuit board typically serves in this context as a carrier for LED components and, if applicable, for control-related, supply-related, or sensor-related functional units. Due to the fastening, the need for screws, clamps, or separate retaining clips is eliminated, which simplifies assembly, reduces the overall size of the luminaire, and minimizes the risk of mechanical damage. At the same time, the circuit board can be positioned exactly and secured in position in the housing, which is advantageous in particular in the case of optically effective elements such as lenses or reflectors. The elastic restoring capability of the fastening regions also enables non-destructive disassembly, for example as part of maintenance work or to replace individual components. The system is thus also particularly suitable for modularly constructed luminaires or luminaires designed to be service-friendly.

In a preferred embodiment, the housing of the luminaire additionally comprises at least one lens, a cover, or an optical diffusion or guiding unit. These elements are part of the lighting system of the luminaire and serve the targeted shaping, diffusion, or shielding of the light emitted by the LED. They can be used individually or in combination in order to achieve the desired light distribution, glare limitation, or protective function. The lens can be designed, for example, as a precision optic made of transparent plastic or glass and can be used for direct light bundling or for creating radiation characteristics such as spot or floodlight. A transparent cover additionally serves the mechanical protection of the LED circuit board as well as protection of the surroundings against contamination or moisture. Optical diffusion elements can distribute the light uniformly over a surface, while light-guiding elements—such as in the form of prisms or light guides—can enable targeted redirection of the light. The retaining connection of the circuit board allows position-accurate positioning of the LED in the housing, so that the optical elements can be aligned exactly with the radiation source. This improves the efficiency and the light quality of the luminaire and at the same time facilitates assembly and replaceability of the components. Since no additional fastening means are necessary, the lighting-technology elements can likewise be integrated into the housing in a space-saving and assembly-friendly manner.

In an advantageous embodiment, the receiving structure of the retaining element is designed such that it can receive the elastically deformable fastening region of the circuit board at least in regions. The receiving structure can have different geometries here, in particular can be designed as a recess, pocket, undercut, latching opening, or as an elastically compliant guide. Depending on the structural design of the retaining element, the receiving structure can form, for example, a defined receiving pocket with a retaining edge into which the deformable region of the circuit board is moved elastically during insertion. Alternatively, an undercut can be designed such that the fastening region, when being pushed in, is guided over an insertion contour and then latches in a positive-locking manner behind a latching edge. Elastically compliant guides, for example in the form of flexible tongues or lamellae in the housing, can also act as receiving structures by receiving the fastening region and fixing it by restoring force.

Further advantageous embodiments are explained in more detail with reference to embodiment examples shown in the drawing.

### BRIEF DESCRIPTION OF THE DRAWINGS

FIG. 1 shows a perspective view of a circuit board and a supporting part,

FIG. 2 shows a perspective view of a circuit board that is fastened to a supporting part,

FIG. 3 shows a sectional view of FIG. 2,

FIG. 4 shows an enlargement of the detail from FIG. 3,

FIG. 5 shows a plan view of an alternative, a circuit board fastened to a supporting part,

FIG. 6 shows a sectional representation of FIG. 5, and

FIG. 7 shows a perspective view of a supporting part with retaining elements and positioning elements.

### DETAILED DESCRIPTION

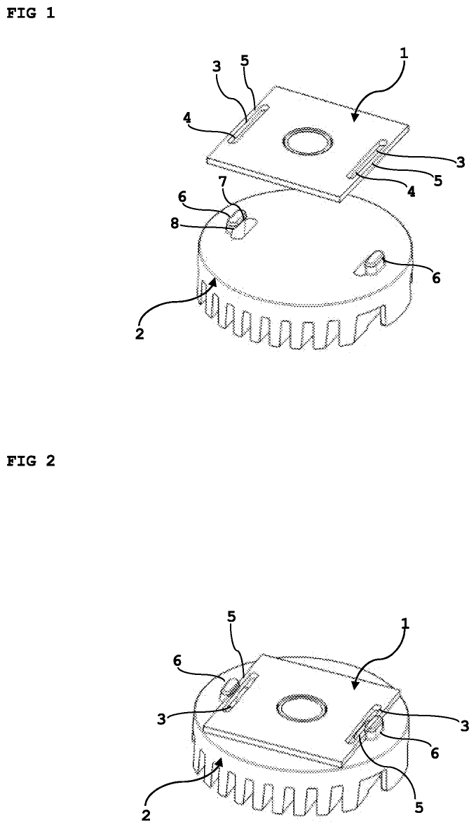

FIG. 1 shows a perspective view of a circuit board and a supporting part. The circuit board 1 is formed in plate shape and is moved in the mounting direction toward the supporting part 2. In the example shown, along two opposite sides of the circuit board 1, two elastically deformable fastening regions 3 are provided. Each fastening region 3 is formed by a slot-shaped recess 4, so that a flexible web 5 is formed that is elastically connected to the remaining circuit board part. In the center of the circuit board 1, a receptacle for, e.g., an LED module can be provided.

The supporting part 2 has two retaining elements 6 in the form of latching lugs, each of which has an insertion ramp 7 and a rear undercut 8. The retaining elements 6 project substantially perpendicularly from a surface of the supporting part 2. The design of the retaining elements 6 is oriented in particular to the geometric properties of the circuit board 1, that is to say, in particular both the height of the retaining elements 6 and the design of the undercut 8 are adapted to the design of the circuit board 1. The arrangement is selected such that, when inserting the circuit board 1, the web 5 is elastically deflected and, after overcoming the insertion ramps 7, latches behind the undercuts 8.

FIG. 2 shows a perspective view of a circuit board that is fastened to a supporting part. The elastically deformable fastening regions 3 are now in an engagement position with the retaining elements 6. The webs 5 have, after elastic deformation, at least partially restored and latch in positive-locking engagement with the undercuts 8 of the latching lugs. The circuit board 1 is thereby secured in position and mechanically fixed without additional fastening elements being required.

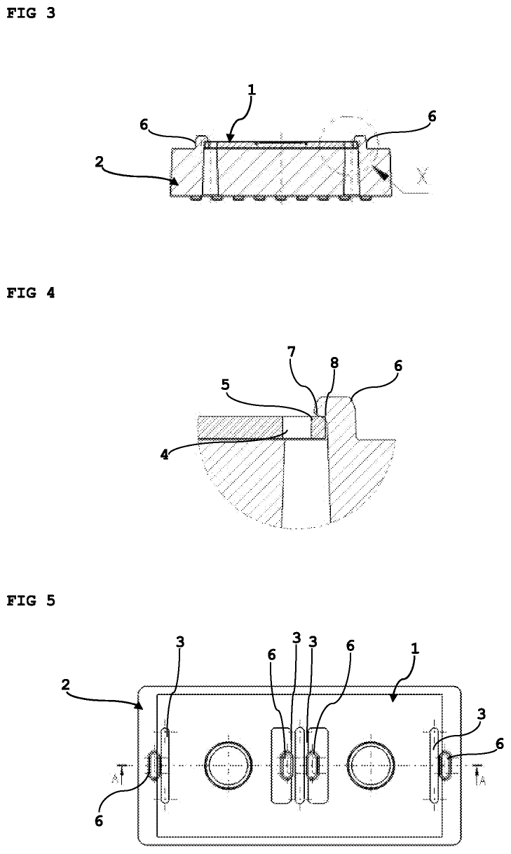

In FIG. 3 a sectional view of FIG. 2 is shown along a vertical plane through one of the fastening points in the mounted state and FIG. 4 an enlarged representation of the latching region marked in FIG. 3. Shown is the circuit board 1 with the fastening region 3, which, by the slot-shaped recess 4, forms a flexible web 5. In the latched state, this lies behind the undercut 8 of the retaining element 6 of the supporting part 2 designed as a latching lug. The positive-locking engagement arises in that the free end region of the web 5 is pressed under preload against the latching lug. The latching lug is part of the retaining element 6, which comprises a receiving structure 9. This structure is designed, for example, as a pocket with undercut 8, into which the elastically deformable web 5 of the circuit board 1 snaps during assembly. The retaining element 6 can have an insertion ramp 7.

The geometry of the recess 4, the latching lug 6, and the undercut 8 is selected such that a defined positive-locking engagement exists, which ensures a reliable and releasable retaining connection.

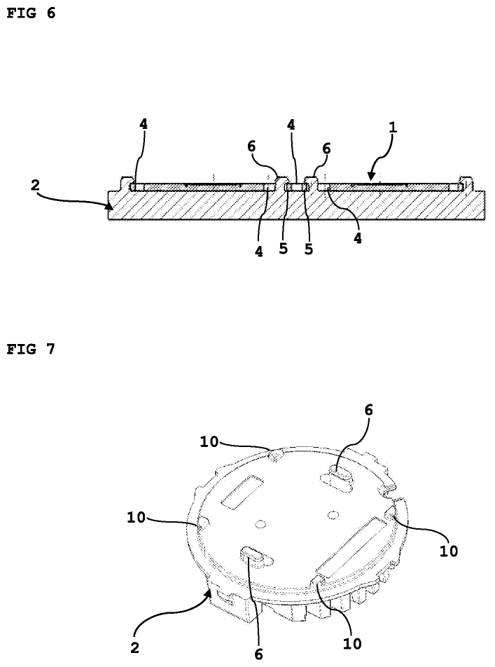

FIG. 5 shows a plan view of an alternative, a circuit board 1 fastened on a supporting part, in which, in addition to the fastening regions 3 in the edge region, a fastening region 3 arranged in the center is also provided, and FIG. 6 a sectional representation of FIG. 5. The central fastening region 3 is likewise formed by slot-shaped recesses 4, so that, in the embodiment, two central, elastically deformable webs 5 are formed. These enable additional fixation of the circuit board 1 in the region of its geometric center and improve support against deformation or vibration.

FIG. 6 shows a vertical section through the central retaining zone of the embodiment according to FIG. 5. The centrally arranged webs 5 of the central fastening regions 3 are in engagement with assigned retaining elements 6 that are located on the supporting part 2. These retaining elements 6 are also formed as a latching lug with insertion ramp and undercut. The functional principle of the latching connection corresponds to that of the edge regions and permits an additional retaining point for central support of the circuit board 1.

In FIG. 7 a perspective view of a supporting part with retaining elements and positioning elements is shown. The supporting part 2 has a surface that is intended and designed for the circuit board to rest on. The circuit board can be held thereon with the retaining elements 6. Depending on the application, the number of retaining elements 6 can vary. In order to prevent, or reduce, slipping of the circuit board, which can be advantageous particularly in the case of a small number of retaining elements 6, positioning elements 10 can be provided on the supporting part 2. In the embodiment shown, the positioning elements 10 are designed as stop edges and are located in the edge region of the supporting part 2, so that lateral movement of an inserted circuit board is prevented by the positioning elements 10.

### LIST OF REFERENCE SIGNS

1 circuit board
2 supporting part
3 elastically deformable fastening region
4 recess
5 web
6 retaining element
7 insertion ramp
8 undercut
9 receiving structure of the retaining element
10 positioning elements

What is claimed is:

1. A fastening system, comprising:
a circuit board (1); and
a supporting part (2),
wherein the circuit board (1) includes an elastically deformable fastening region (3) configured to elastically deform upon insertion into a receiving structure of a retaining element (6) disposed on the supporting part (2), such that the elastically deformable fastening region (3) engages the retaining element (6) to form a mechanical retaining connection.

2. The fastening system of claim 1,
wherein the mechanical retaining connection comprises a positive-locking engagement between the elastically deformable fastening region (3) and the retaining element (6).

3. The fastening system of claim 1,
wherein the elastically deformable fastening region (3) comprises one or more milled recesses, cuts, or openings formed in the circuit board (1).

4. The fastening system of claim 1,
wherein the elastically deformable fastening region (3) is arranged in an edge region of the circuit board (1).

5. The fastening system of claim 1,
wherein the elastically deformable fastening region (3) is arranged near a geometric center of the circuit board (1).

6. The fastening system of claim 1,
wherein the elastically deformable fastening region (3) is one of a plurality of fastening regions (3) including either two fastening regions (3) or four fastening regions (3),
wherein the retaining element (6) is one of a plurality of retaining elements (6) including either two retaining elements (6) or four retaining elements (6),
wherein the fastening regions (3) are arranged opposite one another on opposite sides of the circuit board (1) and configured to engage corresponding retaining elements (6) disposed on the supporting part (2).

7. The fastening system of claim 1,
wherein the circuit board (1) consists of a flexurally elastic material comprising glass-fiber-reinforced plastic (FR4), a flexible composite material, or a metal-core substrate.

8. The fastening system of claim 1,
wherein the retaining element (6) comprises an undercut, a latching lug, or a snap projection.

9. The fastening system of claim 1,
wherein the receiving structure (9) of the retaining element (6) comprises a recess, pocket, an undercut, a latching opening, an elastically compliant guide into which the elastically deformable fastening region (3) of the circuit board (1) can be introduced at least in regions.

10. The fastening system of claim 1,
wherein the circuit board (1) comprises an LED module including surface-mounted devices (SMD) or a chip-on-board (COB) configuration.

11. The fastening system of claim 1,
wherein the mechanical retaining connection is further configured to provide a defined thermal connection and/or electrical isolation between the circuit board (1) and the supporting part (2).

12. The fastening system of claim 1,
wherein the supporting part (2) comprises positioning elements (10) that define a stop for the circuit board (1).

13. A luminaire, comprising:
a housing;
a retaining element (6) disposed on the housing; and
an electronic circuit board (1) comprising at least one light-emitting diode (LED),
wherein the electronic circuit board (1) includes at least one elastically deformable fastening region (3) configured to elastically deform upon insertion into a receiving structure of the retaining element (6) and to engage the retaining element (6) to form a mechanical retaining connection between the electronic circuit board (1) and the housing.

14. The luminaire of claim 13,
wherein the housing comprises at least one lens, a cover, or an optical diffusion or guiding unit.
